(19) United States
(12) Patent Application Publication
(10) Pub. No.: US 2022/0093370 A1
(43) Pub. Date: Mar. 24, 2022

(54) TEXTURED SILICON SEMICONDUCTOR PROCESSING CHAMBER COMPONENTS

(71) Applicants: Lam Research Corporation, Fremont, CA (US); Silfex, Inc., Eaton, OH (US)

(72) Inventors: Lin XU, Fremont, CA (US); Satish SRINIVASAN, Newark, CA (US); Robin KOSHY, Fremont, CA (US); Amir A. YASSERI, San Jose, CA (US); Justin TANG, Clovis, CA (US); Jie ZHANG, Centerville, OH (US); David Joseph WETZEL, Santa Clara, CA (US)

(21) Appl. No.: 17/426,965

(22) PCT Filed: Feb. 5, 2020
(86) PCT No.: PCT/US2020/016710

§ 371 Date: Jul. 29, 2021

Related U.S. Application Data
(60) Provisional application No. 62/801,804, filed on Feb. 6, 2019.
(60) Provisional application No. 62/835,907, filed on Apr. 18, 2019.
(60) Provisional application No. 62/886,100, filed on Aug. 13, 2019.

(51) Int. Cl. H01J 37/32; H01L 21/687; H01L 21/683

(52) U.S. Cl. CPC H01J 37/32642; H01L 21/68757; H01J 2237/334; H01J 37/3255; H01J 37/3244; H01L 21/6831

(57) ABSTRACT

Textured silicon components of a semiconductor processing chamber having hillock-shaped or pyramid-shaped structures on its surface, and a method of texturing such silicon components. The silicon component can be selectively textured using chemical means to form the hillock-shaped structures to increase the surface area of the silicon component to improve polymer adhesion.

### RELATED APPLICATIONS

This application claims priority to and the benefit of U.S. Provisional Application No. 62/801,804, filed on Feb. 6, 2019, U.S. Provisional Application No. 62/835,907, filed on Apr. 18, 2019, and U.S. Provisional Application No. 62/866,100, filed on Aug. 13, 2019, all of which are hereby incorporated herein by reference for all purposes.

### BACKGROUND

The disclosure relates to plasma processing chambers for plasma processing of a semiconductor wafer. More specifically, the disclosure relates to a method of using anisotropic etching to texture silicon parts in semiconductor processing chambers.

Plasma processing is used in forming semiconductor devices. During the plasma processing, components of the plasma processing chamber may be eroded by the plasma. Some plasma processing chambers have all silicon components. Semiconductor processing of wafers having high aspect ratio features requires deposition of thick passivation layers. Such processes are therefore heavy polymer deposition and etch processes. As a result, polymer is deposited on components of the processing chamber but polymer does not adhere well to the chamber components because adhesion of the polymer becomes poorer as the thickness of the polymer increases. This poor adhesion results in polymer flaking, which causes arcing as well as contamination.

It is known that polymer adhesion improves with roughness of the surface to which the polymer is trying to adhere. However, the silicon components cannot be roughened using mechanical means because silicon is a very brittle material. Roughening silicon using mechanical means causes sub-surface damage of the silicon, which can cause flaking and particle issues in the processing chamber. Typically, an acid etch is then performed to remove such sub-surface damage. However, such acid etching actually washes out or removes or smooths out any roughness that was created by the mechanical means. Thus, it would be desirable to be able to use a non-mechanical means to texture silicon surfaces to improve polymer adhesion.

### SUMMARY

According to an embodiment, a component of a semiconductor processing chamber is provided. The component is formed of a material comprising silicon and the component has a textured outer surface comprising a plurality of hillock-shaped structures.

According to another embodiment, a component adapted for use in a semiconductor processing chamber is provided. The component comprises a multi-crystalline silicon body including a textured surface having a surface area. The textured surface comprises an area having bumps or pits.

According to another embodiment, a method is provided for texturing a silicon component of a semiconductor processing chamber. The silicon component, which has an outer surface, is provided. The outer surface is textured to create hillock-shaped structures on the outer surface.

According to yet another embodiment, a method is provided for manufacturing a multi-crystalline silicon component for use in a semiconductor processing chamber. A multi-crystalline silicon body having a surface is provided. The surface of the multi-crystalline silicon body is textured to form a textured surface having a surface area. The textured surface comprises an area having bumps or pits, and the bumps or pits have a height of at least 500 nm.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of a plasma processing chamber according to an embodiment.

FIG. 2A shows hillock-shaped pyramid structures on a silicon component of a semiconductor processing chamber.

FIG. 2B is a side cross-sectional view of an inverted hillock-shaped pyramid structure on a silicon component of a semiconductor processing chamber.

FIG. 3 is a high level flow chart of an embodiment of a method for texturing a silicon containing component of a semiconductor processing chamber.

FIG. 4 is a high level flow chart of a method for texturing a silicon containing component of a semiconductor processing chamber according to another embodiment.

FIG. 5 is a high level flow chart of another embodiment of a method for texturing a silicon containing component of a semiconductor processing chamber.

FIG. 6 is a high level flow chart of a method for texturing a silicon containing component of a semiconductor processing chamber according to yet another embodiment.

FIG. 7 is a magnified image of a textured surface of multi-crystalline silicon body according to an embodiment.

FIG. 8 is a high level flow chart of an embodiment of a method for texturing a surface of a multi-crystalline silicon body.

### DETAILED DESCRIPTION OF EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

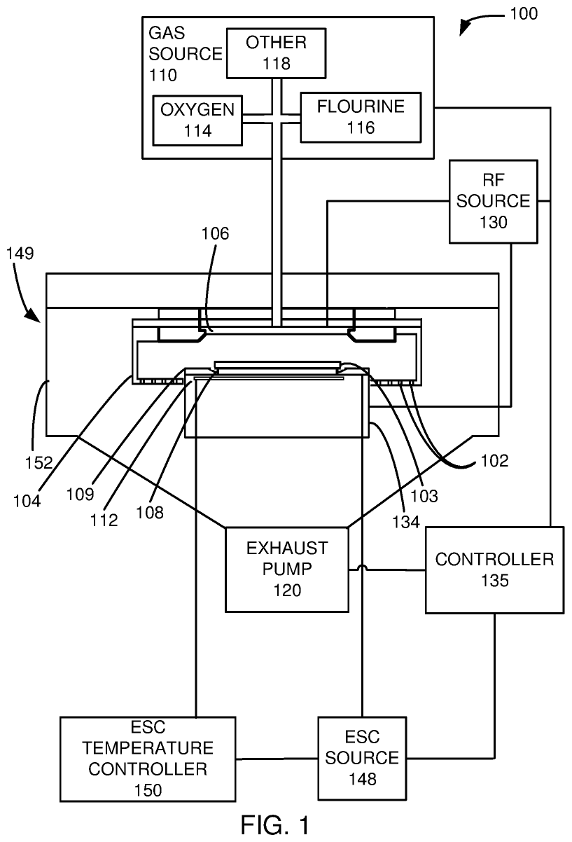

FIG. 1 is a schematic view of an embodiment of a plasma processing reactor 100 that may be used for processing a semiconductor wafer. In one or more embodiments, a plasma processing chamber 100 comprises a gas distribution plate 106 providing a gas inlet and an electrostatic chuck (ESC) 108, within an etch chamber 149, enclosed by a chamber wall 152. Within the etch chamber 149, a wafer 103 is positioned over the ESC 108, which is a wafer support. An edge ring 109 surrounds the ESC 108. An ESC source 148 may provide a bias to the ESC 108. A gas source 110 is connected to the etch chamber 149 through the gas distribution plate 106. In this embodiment, the gas source comprises an oxygen containing component source 114, a fluorine containing component source 116, and one or more other gas sources 118. An ESC temperature controller 150 is connected the ESC 108.

A radio frequency (RF) source 130 provides RF power to a lower electrode and/or an upper electrode, which in this embodiment are the ESC 108 and the gas distribution plate 106. In an exemplary embodiment, 400 kilohertz (kHz), 60 megahertz (MHz), 2 MHz, 13.56 MHz, and/or 27 MHz power sources make up the RF source 130 and the ESC source 148. In this embodiment, the upper electrode is grounded. In this embodiment, one generator is provided for each frequency. In other embodiments, the generators may be separate RF sources, or separate RF generators may be connected to different electrodes. For example, the upper electrode may have inner and outer electrodes connected to different RF sources. Other arrangements of RF sources and electrodes may be used in other embodiments. In other embodiments, an electrode may be an inductive coil.

A controller 135 is controllably connected to the RF source 130, the ESC source 148, an exhaust pump 120, and the gas source 110. A high flow liner 104 is a liner within the etch chamber 149, which confines gas from the gas source and has slots 102, which allows for a controlled flow of gas to pass from the gas source 110 to the exhaust pump 120.

As discussed above, high aspect ratio semiconductor processes can involve heavy polymer deposition and etch processes. Some plasma processing chambers have all silicon components, and such silicon chamber components are typically manufactured with a ground/lapped/polished surface finish with a final mixed acid etching (MAE) process to remove the depth of damage. However, the etching to smooth out the surfaces is actually counterproductive as these surface finishes do not have sufficient high frequency roughness features and so polymer heavy deposition processes have issues related to poor polymer adhesion onto the chamber surfaces and therefore result in polymer flaking and particle generation. As noted above, such polymer flaking also results in undesirable arcing and contamination. Texturing of single crystal silicon surfaces using physical means is challenging because the depth of damage caused by these physical means may need to be removed by a MAE process and that would wash out the texture that is necessary for adhesion.

Polymer adhesion onto the silicon chamber surfaces improves with increased surface roughness, as the surface area for adhesion is increased making delamination more difficult. However, silicon cannot be roughened or textured mechanically due to the very brittle nature of silicon, as noted above. Thus, chemical means for texturing the silicon surfaces is more practical.

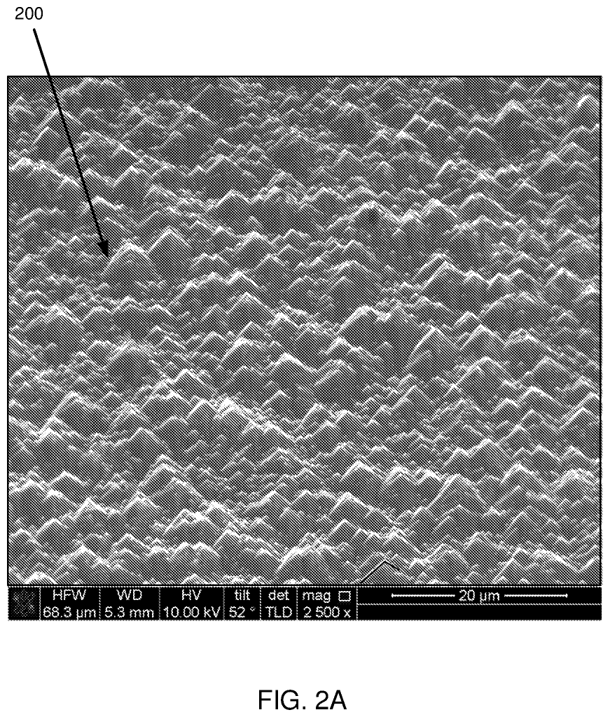

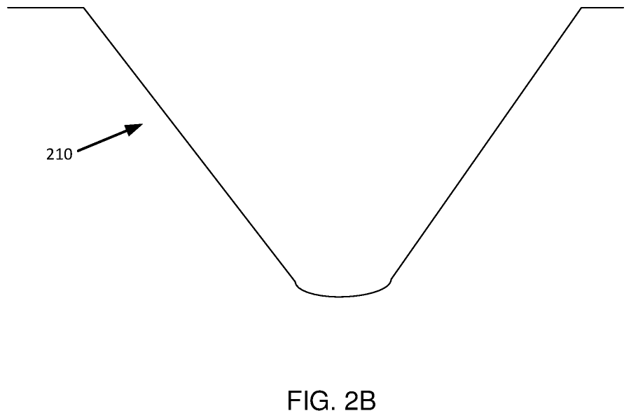

According to an embodiment of the processing chamber 100, the upper electrode 106 (showerhead) is formed of single crystal (1-0-0 crystal orientation) silicon and can be textured to have hillock-shaped structures 200 on the surface, as shown in FIG. 2A, using the methods described herein. Similarly, other chamber components, such as the high flow liner 104 and the edge ring 109, are also formed of material comprising silicon and can be textured using the methods described herein. In other embodiments, a chamber component formed of a silicon material having a 1-0-0 crystal orientation is textured using the methods described herein. It will be understood that, theoretically, silicon having other crystal orientations (except 1-1-1) can be textured using the methods described herein.

According to an embodiment, anisotropic etching of single crystal silicon can be used to create uniform pyramid-shaped or hillock-shaped structures for texturing the silicon surfaces of components in the plasma processing chamber 100 to increase the surface area. The structures are generally four-sided structures. The texturing is tunable in that the shape of the hillocks or pyramids, the height (peak to valley) of the hillocks or pyramids, and the reflectance of the hillocks or pyramids can be selected by tailoring the chemistry and other processing conditions used for texturing. The resulting texture is related to and dependent on the specific chemistry and process conditions used for the chemical etching as well as time of exposure to the chemistry.

It will be understood that the reflectance of a surface is measured as a percentage of incident light reflected from surface and typically includes measurement of both the specular and diffuse reflectance. It is typically measured using a spectrophotometer coupled to an integrating sphere. In accordance with embodiments described herein, average reflectance of the hillocks or pyramids is typically in a range of about 5-30% between 400-800 nm of light.

According to some embodiments, the texturing processes described herein are carried out in a temperature range of about 50-100° C. In a particular embodiment, the silicon chamber parts are textured at a temperature of about 80° C., which is close to the boiling point of IPA. It will be noted that, in some embodiments, IPA needs to be replenished during the texturing process. According to a particular IPA-based chemistry, the texturing process is carried out in a temperature range of about 50-100° C. with KOH (1-10 wt %) and IPA (1-19 wt %) for 1-60 minutes. Alternatively, non-IPA-based chemistries can be used for texturing silicon chamber parts as well, as mentioned in more detail below. The parameters given above are based on texturing processes for silicon components of plasma semiconductor processing chamber such as those from the Flex® family of products, which are made by Lam Research Corporation of Fremont, Calif.

The texturing can be used for selective patterning or preferential etching of silicon parts, such as the edge ring 109, the gas distribution plate 106, and the high flow liner 104, in the chamber 100. Such selective patterning or preferential etching can be accomplished using a mask. For example, different areas can be patterned and masked to create hillocks having different heights or different densities or different surface roughness. In some embodiments, a textured surface can be used as a mask to generate further texturing.

In one particular embodiment of the plasma processing chamber 100, the upper electrode (showerhead) 106 is formed of single crystal silicon and is selectively textured to have increased surface roughness in its central portion to locally improve the adhesion. This, in some cases, could afford adhesion selectivity due to non-uniformities in the process and subsequent polymer deposition and etching. In other embodiments, the silicon component is an edge ring or a high flow liner, and the component may or may not be selectively textured.

The average height, from peak to valley of the hillocks, can be in a range of about 500 nanometers to 20 microns. In some embodiments, the height of a hillock can be up to 20% lower or higher than the average height of the hillocks. According to some embodiments, the heights of the hillock-shaped or pyramid-shaped structures are substantially similar to the polymer thickness to improve adhesion of the deposited polymers. In addition to single crystal silicon, polysilicon, multi-crystalline silicon, doped silicon, and silicon oxide (SiO₂) can also be textured using the methods described herein.

Potassium hydroxide (KOH) and sodium hydroxide (NaOH) based chemistries can be used for texturing the silicon chamber parts, preferably at elevated temperatures, to create the pyramid-shaped or hillock-shaped structures. The pyramid-shaped or hillock-shaped structures result in increased high frequency roughness of the silicon surface, which helps in improving polymer adhesion thereby reducing or eliminating flaking. The resulting textured outer surface of the silicon component can have a surface roughness in a range of about 0.2-2 microns. According to some embodiments, the surface area of the chamber part is increased by up to 1000% after texturing according to the embodiments described herein.

It will be noted that the use of KOH alone to etch silicon results in isotropic etching and will not result in the desired texture with the hillock-shaped structures. The presence of an additive, such as an organic alcohol or a surfactant, in KOH can be used for creating substantially uniform pyramids or hillocks on silicon surfaces. According to a particular embodiment, the additive is isopropyl alcohol (IPA). Therefore, according to some embodiments, a KOH+IPA solution can be used to create the pyramid-shaped or hillock-shaped structures. IPA, however, can be a volatile material. Thus, in other embodiments, other additives, including deionized water, surfactants and other IPA-free additives, can be used instead to create a textured surface.

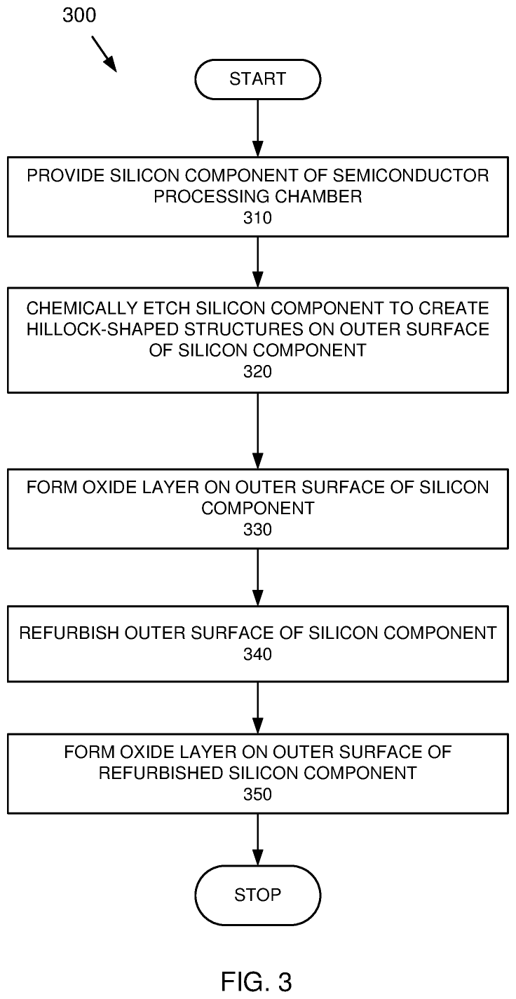

With reference to FIG. 3, an embodiment of a method 300 for texturing a silicon component of a semiconductor processing chamber is described. The method 300 begins with providing the silicon component of a semiconductor processing chamber in Step 310. The silicon component has an outer surface. According to some embodiments, the silicon component is formed of single crystal silicon. In other embodiments, the silicon component is polysilicon or doped silicon. In Step 320, the silicon component is chemically etched to create hillock-shaped structures on the outer surface of the silicon component. According to an embodiment, the silicon component is chemically etched using KOH-based chemistries to anisotropically etch the silicon surface. In another embodiment, the silicon component is chemically etched with NaOH-based chemistries to anisotropically etch the silicon surface.

In Step 330, if desired, an oxide layer can be formed on the outer surface of the silicon component to allow for even better polymer adhesion. The thickness of the oxide layer is preferably in a range of about 10 nm-100 microns. According to an embodiment, the outer layer can be thermally oxidized in-situ to form the oxide layer. According to another embodiment, a silicon oxide (SiO2) layer is formed on the surface to improve adhesion. The SiO₂ can be deposited by chemical vapor deposition (CVD), also in-situ. In an alternative embodiment, SiCl₄+O₂ or O₂ plasma can be deposited by CVD or plasma enhanced CVD (PECVD) to form the oxide layer. In still other embodiments, other polymers can be deposited to form a layer on the outer surface to promote further polymer adhesion.

In Step 340, after the hillock-shaped structures have eroded as a result of use of the semiconductor processing chamber for processing semiconductor wafers, the outer surface of the silicon component can be refurbished. For example, if the height of the pyramids or hillocks becomes lower than 500 nanometers, then a refurbishment process may be performed to increase the surface area and extend the lifetime of the component. In some embodiments, the outer surface of the silicon component is refurbished by chemically re-etching the outer surface. In other embodiments, the outer surface of the silicon component is refurbished by a template-assisted method or refurbished by using existing eroded hillock-shaped textured silicon surfaces as an etch mask template to tune or regenerate surface morphology of the silicon component. In Step 350, if desired, an oxide layer can be formed on the outer surface of the refurbished silicon component to allow for even better polymer adhesion similar to Step 330. In some embodiments, the oxide layer forming steps of 330 and 350 can be omitted.

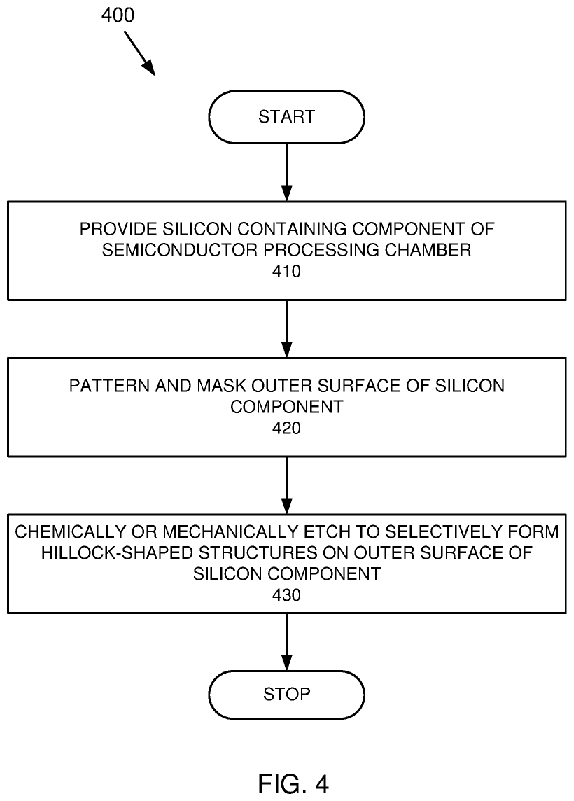

FIG. 4 is a flow chart of another embodiment of a method 400 for selectively texturing a silicon component of a semiconductor processing chamber. In Step 410, a silicon containing component of a semiconductor chamber is provided. The outer surface of the silicon containing component is then selectively textured in at least a portion of the component to increase the surface area. The outer surface can be selectively textured by first patterning and masking the outer surface of the silicon component in Step 420, followed by chemical or mechanical etching in Step 430 to selectively form hillock-shaped structures on the outer surface of the silicon component.

According to another embodiment, instead of pyramid-shaped or hillock-shaped structures, inverted hillock-shaped or inverted pyramid structures can be created on the silicon surfaces of the plasma processing chamber 100 to increase the surface area of the silicon surfaces to improve polymer adhesion. As shown in FIG. 2B, these inverted pyramids 210 are similar to the pyramid-shaped or hillock-shaped structures, only they are inverted. According to some embodiments, the inverted pyramids 210 can be created using techniques involving photolithography laser processes, etc.

A simpler method of texturing such inverted pyramids on silicon surfaces involves the use of maskless Cu-nanoparticles (NPs) assisted anisotropic etching of crystalline silicon in a Cu(NO₃)₂/HF/H₂O₂/H₂O mixture, preferably at about 50° C. for about 15 minutes. According to this embodiment, after texturing, the inverted pyramids can then be cleaned using concentrated nitric acid in a sonication bath for at least about 20 minutes to remove residual Cu-NPs. The parameters given above are based on texturing processes for silicon components of plasma semiconductor processing chamber such as those from the Flex® family of products, which are made by Lam Research Corporation of Fremont, Calif.

The texturing can be used for selective patterning or preferential etching of silicon parts, such as the edge ring 109, the gas distribution plate 106, and the high flow liner 104, in the chamber 100. Such selective patterning or preferential etching can be accomplished using a mask. For example, different areas can be patterned and masked to create inverted hillocks having different heights or different densities or different surface roughness. In some embodiments, texturing itself can be used as a mask to generate further texturing.

In one particular embodiment of the plasma processing chamber 100, the upper electrode (showerhead) 106 is formed of single crystal silicon and is selectively textured to have increased surface roughness in its central portion to locally have control over the adhesion. This, in some cases, could afford adhesion selectivity due to non-uniformities in the process and subsequent polymer deposition and etching. In other embodiments, the silicon component is an edge ring or a high flow liner, and the component may or may not be selectively textured.

The texturing of the inverted pyramid structures is also tunable in that the shape of the hillocks or pyramids, the height (peak to valley) of the hillocks or pyramids, and the reflectance of the hillocks or pyramids can be selected by tailoring the chemistry and other processing conditions used for texturing. The morphology of the inverted pyramids can be controlled by tailoring the etching time, etching temperature, as well as the concentration of the Cu(NO₃)₂/HF/H₂O₂/H₂O mixture. According to some embodiments, the texturing processes for creating inverted pyramid structures are carried out in a temperature range of about 40-70° C.

According to an embodiment, before texturing using the Cu(NO₃)₂/HF/H₂O₂/H₂O mixture, the crystalline silicon with 1-0-0 crystal orientation can be rinsed in acetone to remove organic contaminants followed by a rinse using deionized water.

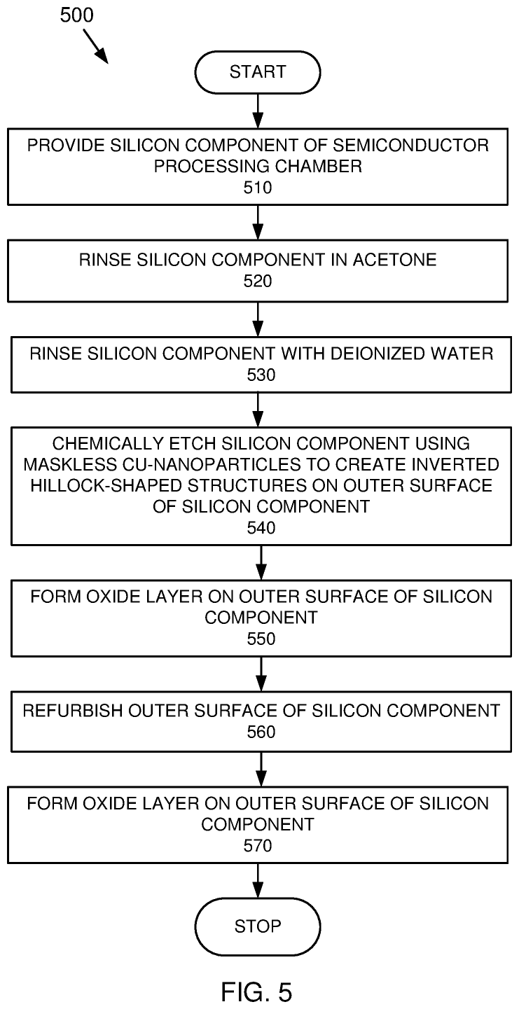

With reference to FIG. 5, an embodiment of a method 500 for texturing a silicon component of a semiconductor processing chamber is described. The method 500 begins with providing the silicon component of a semiconductor processing chamber in Step 510. The silicon component has an outer surface. According to some embodiments, the silicon component is formed of single crystal silicon. In other embodiments, the silicon component is polysilicon or doped silicon. In Step 520, the crystalline silicon component can be rinsed in acetone to remove organic contaminants followed by a rinse with deionized water in Step 530.

In Step 540, the silicon component is chemically etched to create inverted hillock-shaped structures on the outer surface of the silicon component. According to an embodiment, the silicon component is chemically etched using maskless Cu-nanoparticles (NPs) to anisotropically etch the silicon surface. A Cu(NO₃)₂/HF/H₂O₂/H₂O mixture can be used to texture the silicon surface, preferably at a temperature of about 50° C. and for about 15 minutes.

In Step 550, if desired, an oxide layer can be formed on the outer surface of the silicon component to allow for even better polymer adhesion. The thickness of the oxide layer is preferably in a range of about 10 nm-100 microns. According to an embodiment, the outer layer can be thermally oxidized in-situ to form the oxide layer. According to another embodiment, a silicon oxide (SiO2) layer is formed on the surface to improve adhesion. The SiO₂ can be deposited by chemical vapor deposition (CVD), also in-situ. In an alternative embodiment, SiCl₄+O₂ or O₂ plasma can be deposited by CVD or plasma enhanced CVD (PECVD) to form the oxide layer. In still other embodiments, other polymers can be deposited to form a layer on the outer surface to promote further polymer adhesion.

In Step 560, after the inverted hillock-shaped structures have eroded as a result of use of the semiconductor processing chamber for processing semiconductor wafers, the outer surface of the silicon component can be refurbished. For example, if the height of the inverted pyramids or inverted hillocks becomes lower than about 500 nanometers, then a refurbishment process may be performed to increase the surface area and extend the lifetime of the component. In some embodiments, the outer surface of the silicon component is refurbished by chemically re-etching the outer surface. In other embodiments, the outer surface of the silicon component is refurbished by a template-assisted method or refurbished by using existing eroded inverted hillock-shaped textured silicon surfaces as an etch mask template to tune or regenerate surface morphology of the silicon component.

In Step 570, if desired, an oxide layer can be formed on the outer surface of the refurbished silicon component to allow for even better polymer adhesion similar to Step 550. In some embodiments, the oxide layer forming step of 570 can be omitted.

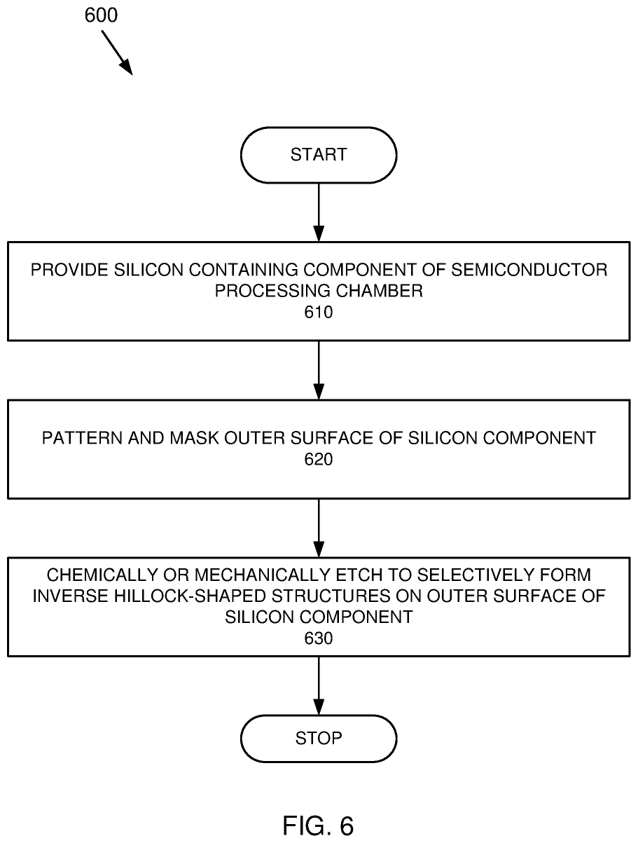

FIG. 6 is a flow chart of another embodiment of a method 600 for selectively texturing a silicon component of a semiconductor processing chamber. In Step 610, a silicon containing component of a semiconductor chamber is provided. The outer surface of the silicon containing component is then selectively textured in at least a portion of the component to increase the surface area. The outer surface can be selectively textured by first patterning and masking the outer surface of the silicon component in Step 620, followed by chemical or mechanical etching in Step 630 to selectively form inverted hillock-shaped structures on the outer surface of the silicon component.

According to another embodiment, the upper outer electrode 116 and the high flow liner 104 of the semiconductor chamber 100 are formed from multi-crystalline silicon. A multi-crystalline silicon body is cast. The cast multi-crystalline silicon body has an outer surface that is textured to form hillock-shaped structures comprising bumps. In this embodiment, the bumps have a height of at least 500 nm where the area of the bumps is formed over at least 90% of an entire area of the textured surface of the multi-crystalline silicon body. In various embodiments, the textured surface of the multi-crystalline silicon body is the entire surface of the multi-crystalline silicon body.

In an embodiment, a MAE process uses a mixture of nitric acid, hydrofluoric acid, and acetic acid at a molar ratio of 4:1:6, respectively. A surface of the silicon body is exposed to the mixed acid to etch and create the textured surface.

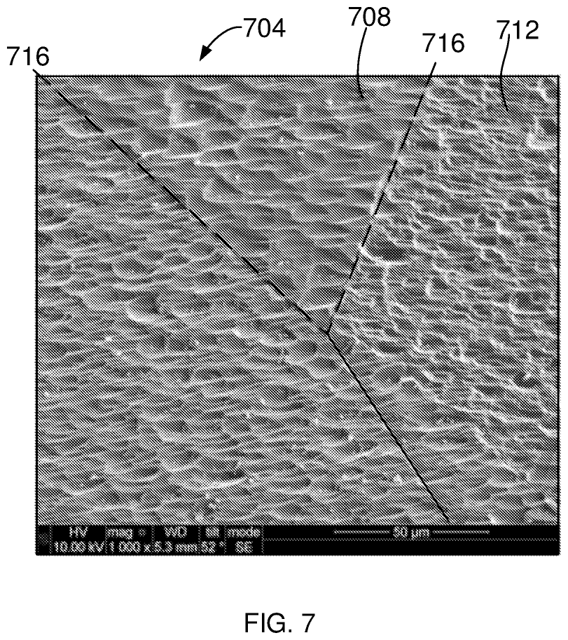

FIG. 7 is a magnified image of a textured surface 704 of the silicon body. The textured surface 704 of the silicon body has a first crystalline grain 708 and a second crystalline grain 712. A grain boundary indicated by dashed lines 716 is between the first crystalline grain 708 and the second crystalline grain 712. The texturing causes the texture of the grain surface of the first crystalline grain 708 to be different than the texture of the grain surface of the second crystalline grain 712, as shown in FIG. 7. Without being bound by theory, the different crystalline grains 708, 712 have different orientations. The etch is anisotropic, depending on crystal orientation. Therefore, different crystalline grains 708, 712 have different textures. However, the texturing in this embodiment results in the different grain surfaces having textured surfaces of hillock-shaped structures comprising bumps. In this embodiment, the bumps have a height of at least 500 nm and where the area of the bumps is formed over at least 90% of an area of the textured surface of the multi-crystalline silicon body. Therefore, although the textures of the different grain surfaces are different, certain characteristics of the different grain structures are uniform, e.g., by having bump height and area percentage within a threshold range.

According to some embodiments, the texturing processes described herein are carried out in a temperature range of about 5-80° C. In other embodiments, the temperature range is about 25° C.-100° C. The texturing can be used for multi-crystalline silicon parts adapted for use in the semiconductor processing chamber 100, such as the edge ring 109, the gas distribution plate 106, the upper outer electrode 116, and the high flow liner 104. In some embodiments, the texturing may be performed for 60 seconds to 100 seconds.

The average height, from peak to valley of the hillocks, can be in a range of about 500 nanometers to 20 microns. In some embodiments, the height of a hillock can be up to 20% lower or higher than the average height of the hillocks. According to some embodiments, the heights of the hillock-shaped structures are substantially similar to the polymer thickness to help improve adhesion of the deposited polymers.

According to some embodiments, the surface area of the chamber part is increased by up to 1000% after texturing according to the embodiments described herein.

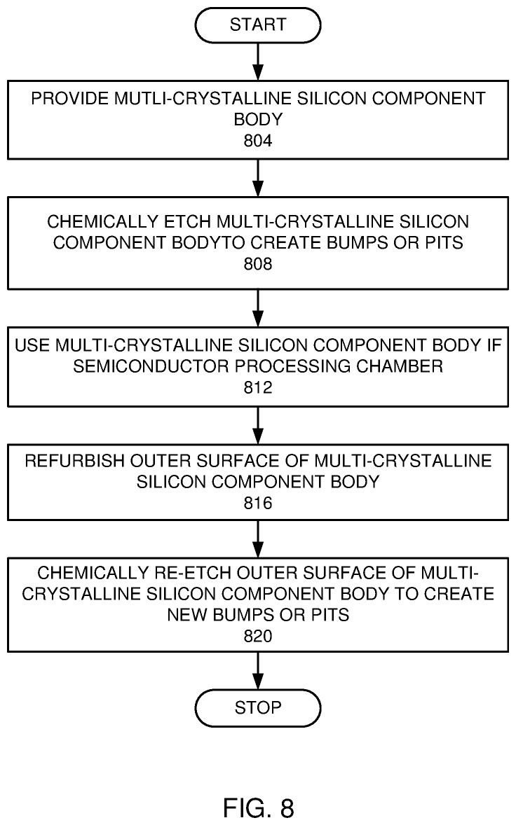

With reference to FIG. 8, an embodiment of a method for texturing a multi-crystalline silicon component body adapted for use in a semiconductor processing chamber 100 is described. The method begins with providing the multi-crystalline silicon component body of a semiconductor processing chamber (step 804). In this embodiment, the multi-crystalline silicon component body is the upper outer electrode 116 that has been formed by casting. The multi-crystalline silicon component body has an outer surface. The multi-crystalline silicon component body is chemically etched to create bumps or pits on the outer surface of the multi-crystalline silicon component body (step 808). These bumps or pits can be hillock-shaped structures, with the pits being inverted hillock-shaped structures. According to an embodiment, the multi-crystalline silicon component body is chemically etched using a mixed acid of nitric acid, hydrofluoric acid, and acetic acid at a molar ratio of 4:1:6, respectively. The multi-crystalline silicon component body is used in the semiconductor processing chamber 100 (step 812). Use in the semiconductor processing chamber 100 causes the hillock-shaped structures to erode. For example, the height of the hillocks may become lower than 500 nanometers. In addition, deposits may build up on parts of the outer surface of the multi-crystalline silicon component body. The outer surface of the used multi-crystalline silicon component body is refurbished to increase the surface area and extend the lifetime of the component (step 816). In this embodiment, the outer surface of the silicon component is refurbished by polishing the surface of the multi-crystalline silicon component body. The polishing removes contaminants that have deposited on the surface during usage and smooths the surface of the multi-crystalline silicon component body. The polishing may remove between 0.5 mm to 2 mm of the surface of the multi-crystalline silicon component body. The surface of the multi-crystalline silicon component body is then chemically re-etched by using the above etching recipe to create new bumps or bits (e.g., hillock shaped structures) (step 820). The multi-crystalline silicon component can then again be used in the semiconductor processing chamber 100.

According to another embodiment, instead of hillock-shaped structures forming bumps, the hillock-shaped structures form pits or divots. In various embodiments, different ratios of the MAE may be used. Instead of an MAE process with a mixed acid of nitric acid, hydrofluoric acid, and acetic acid at a molar ratio of 4:1:6, other embodiments may have an MAE with a mixed acid of nitric acid, hydrofluoric acid and acetic acid at other ratios, where the molarity of the acetic acid is at least twice the molarity of the hydrofluoric acid and the molarity of the acetic acid is greater than the molarity of the nitric acid. It was unexpectedly found that such an etch process would provide a uniform texture across grain boundaries in that the bumps or pits have heights and areas within a specified range. The texturing is different for the different multi-crystalline grains, but uniform within a threshold. In other embodiments, other anisotropically etching processes may be used to provide a texture that is uniform across grain boundaries so that bumps or pits provided by the texturing is within a specified range.

In various embodiments, the multi-crystalline silicon component body is cast. Such casting may be performed by melting the silicon, pouring the silicon in a mold, and cooling the silicon to form a bulk multi-crystalline silicon body, instead of forming the silicon into a mono-crystalline structure.

Although only a few embodiments of the invention have been described in detail, it should be appreciated that the invention may be implemented in many other forms without departing from the spirit or scope of the invention. In view of all of the foregoing, it should be apparent that the present embodiments are illustrative and not restrictive and the invention is not limited to the details given herein, but may be modified within the scope and equivalents of the appended claims.

What is claimed is:

1. A component of a semiconductor processing chamber, the component formed of a material comprising silicon and the component comprising a textured outer surface comprising a plurality of hillock-shaped structures.

2. The component as recited in claim 1, wherein the component is at least one of an electrode, edge ring, and a liner.

3. The component as recited in claim 1, wherein the material is one of single crystal silicon, doped silicon, polysilicon, and multi-crystalline silicon.

4. The component as recited in claim 1, wherein an average height of the plurality of hillock-shaped structures is in a range of about 500 nanometers to 20 microns.

5. The component as recited in claim 1, wherein the textured outer surface has a surface roughness in a range of about 0.2-2 microns.

6. The component as recited in claim 1, wherein an average reflectance of the plurality of hillock-shaped structures is in a range of about 5-30% between 400-800 nm of light.

7. The component as recited in claim 1, wherein the plurality of hillock-shaped structures are inverted hillock-shaped structures.

8. A component adapted for use in a semiconductor processing chamber, comprising a multi-crystalline silicon body including a textured surface having a surface area, wherein the textured surface comprises an area having a plurality of bumps or pits.

9. The component as recited in claim 8, wherein the textured surface comprises a plurality of grain surfaces including a first grain surface and a second grain surface, wherein the first grain surface has a texture that is different from that of the second grain surface.

10. The component as recited in claim 8, wherein the multi-crystalline silicon body is a cast multi-crystalline silicon body.

11. The component as recited in claim 8, wherein the multi-crystalline silicon body is a bulk multi-crystalline silicon body.

12. The component as recited in claim 8, wherein the component is at least one of an electrode, edge ring, and a liner.

13. The component as recited in claim 8, wherein an average height of the plurality of bumps or pits is in a range of about 500 nanometers to 20 microns.

14. The component as recited in claim 8, wherein the area having the plurality of bumps or pits is formed over at least 90% of an entire surface area of the textured surface.

15. A method for texturing a silicon component of a semiconductor processing chamber, the method comprising:
providing the silicon component having an outer surface; and
texturing the outer surface to create a plurality of hillock-shaped structures on the outer surface.

16. The method as recited in claim 15, wherein the silicon component is selectively textured.

17. The method as recited in claim 15, wherein texturing is achieved by chemically etching the outer surface.

18. The method as recited in claim 17, wherein chemically etching is performed using a solution comprising potassium hydroxide.

19. The method as recited in claim 17, wherein chemically etching is performed using a solution comprising sodium hydroxide.

20. The method as recited in claim 17, wherein chemically etching is performed using an acid mixture comprising nitric acid, acetic acid and hydrofluoric acid.

21. The method as recited in claim 15, wherein the silicon component comprises one of single crystal silicon, doped silicon, polysilicon, and multi-crystalline silicon.

22. The method as recited in claim 15, wherein the plurality of hillock-shaped structures have a first average height in a range of about 500 nanometers to 20 microns.

23. The method as recited in claim 22, further comprising refurbishing the outer surface after the plurality of hillock-shaped structures have eroded and have a second average height, wherein refurbishing comprises re-etching the outer surface to regenerate one or more of the plurality of hillock-shaped structures to have a third average height, wherein the second average height is less than the first average height and the third average height.

24. The method as recited in claim 15, further comprising forming an oxide layer on the outer surface after texturing the outer surface.

25. The method as recited in claim 15, wherein texturing is achieved by patterning using soft or hard masks followed by etching the outer surface.

26. The method as recited in claim 15, wherein texturing creates a textured surface that can be used as a mask to generate further texturing.

27. The method as recited in claim 15, wherein the plurality of hillock-shaped structures are inverted hillock-shaped structures.

28. The method as recited in claim 27, wherein texturing is achieved by chemically etching the outer surface, wherein chemically etching is performed using a solution comprising Cu(NO₃)₂/HF/H₂O₂/H₂O.

29. A method for manufacturing a multi-crystalline silicon component for use in a semiconductor processing chamber, the method comprising:
providing a multi-crystalline silicon body having a surface; and
texturing the surface of the multi-crystalline silicon body to form a textured surface having a surface area, wherein the textured surface comprises an area having a plurality of bumps or pits, wherein the plurality of bumps or pits have a height of at least 500 nm.

30. The method, as recited in claim 29, wherein texturing comprises anisotropically etching the surface.

31. The method, as recited in claim 29, wherein anisotropically etching the surface comprises exposing the surface to a mixed acid.

32. The method, as recited in claim 29, wherein providing the multi-crystalline silicon body comprises casting the multi-crystalline silicon body.

33. The method, as recited in claim 29, wherein providing the multi-crystalline silicon body comprises polishing a used multi-crystalline silicon body.

34. The method, as recited in claim 29, wherein texturing comprises exposing the surface to a mixture of nitric acid, hydrofluoric acid, and acetic acid.

35. The method, as recited in claim 34, wherein the hydrofluoric acid has a molarity, and the acetic acid has a molarity, and wherein the molarity of the acetic acid is at least twice the molarity of the hydrofluoric acid.

36. The method, as recited in claim 34, wherein the nitric acid has a molarity, and the acetic acid has a molarity, and wherein the molarity of the acetic acid is greater than the molarity of the nitric acid.

37. The method, as recited in claim 29, wherein the area having the plurality of bumps or pits is formed over at least 90% of an entire area of the surface area.
